(19) United States
(12) Patent Application Publication
(10) Pub. No.: US 2025/0115376 A1
(43) Pub. Date: Apr. 10, 2025

(54) HEAT CONTROL STRUCTURE AND ARTIFICIAL SATELLITE EQUIPPED WITH HEAT CONTROL STRUCTURE

(71) Applicant: Panasonic Holdings Corporation, Osaka (JP)

(72) Inventors: Mengu CHO, Fukuoka (JP); Hirokazu MASUI, Fukuoka (JP); Ryou KUWABARA, Osaka (JP); Takashi TSURUTA, Osaka (JP); Kazuma OIKAWA, Osaka (JP); Masato MORI, Hyogo (JP)

(21) Appl. No.: 18/987,783

(22) Filed: Dec. 19, 2024

Related U.S. Application Data
(63) Continuation of application No. PCT/JP2023/015802, filed on Apr. 20, 2023.

(30) Foreign Application Priority Data
Jun. 30, 2022 (JP) 2022-105868

(51) Int. Cl. B64G 1/58; F28F 21/02

(52) U.S. Cl. CPC B64G 1/58; F28F 21/02

(57) ABSTRACT

A heat control structure includes sheet-like or plate-like graphite members, a first holding member holding the graphite members at first ends in a longitudinal direction of the graphite members with basal planes of the graphite members arrayed in parallel and with edge planes orthogonal to the basal planes being exposed, and a second holding member holding the graphite members at second ends opposite to the first ends of the graphite members with the basal planes arrayed in parallel and with the edge planes being exposed. The edge planes exposed at the first ends of the graphite members come into contact with a heat control target to function as heat transfer surfaces through which heat energy is input, and the edge planes exposed at the second ends come into contact with a heat dissipation target to function as heat transfer surfaces through which heat energy is dissipated.

### CROSS-REFERENCE TO RELATED APPLICATIONS

The present application is a continuation of PCT/JP2023/015802 filed Apr. 20, 2023, which claims priority to Japanese Patent Application No. 2022-105868, filed Jun. 30, 2022, the entire contents of each of which are incorporated herein by reference.

### TECHNICAL FIELD

The present disclosure relates to a heat control structure for equipment requiring heat control, such as an electronic device, and to an artificial satellite including the heat control structure.

### BACKGROUND ART

Spacecraft are exposed to both low and high temperature environments, so that it is essential to keep the onboard equipment within an acceptable temperature range. In conventional large satellites, etc., electronic devices and heat pipes were arranged inside the housing. However, in today's artificial satellites, which require small size, light weight and high density packaging, it is necessary to diffuse the local heat generated by semiconductors while stabilizing the operation on the low temperature side, rendering thermal design more difficult. Normally, thermal design is done based on the high temperature environment, whereas in low temperature environment, temperature control is performed by heating with polyimide heaters or the like.

In Patent Document 1 (JP3084814), a space radiator having a refrigerant flow path pipe is described, but this has a rigid structure. Furthermore, a prototype has been created in which a metal pipe is passed through the back of the display for cooling a personal computer or the like.

In terms of mechanics, thermal louvers and deployable radiators are known as conventional techniques for heat control of spacecraft. Thermal louvers can passively deal with changes in the thermal environment, but they do not increase the amount of heat dissipation. On the other hand, deployable radiators can improve heat dissipation and reduce weight by using graphite in the heat dissipation part (see, e.g., Patent Document 2: JP2008265522A).

Meanwhile, for heat control in terrestrial applications, electronic devices and the like are the targets of heat control, and the development of electronic devices is becoming more and more sophisticated. Examples of such electronic devices include: electronic devices capable of operating at high processing speeds and high frequencies and having small size and more complex power requirements; and other technologically advanced devices such as microprocessors, electronic and electrical components, and integrated circuits of devices; as well as high power optical devices. Extremely high temperatures can occur in electronic devices. However, microprocessors, integrated circuits, and other high performance electronic components generally only operate efficiently under a certain range of threshold temperatures. Excessive heat generated during the operation of electronic components is not only detrimental to their inherent performance, but can also impair the performance and reliability of the entire system, and may even cause the system to fail. The increasingly widened range of environmental conditions, including extreme temperatures expected from the operation of electronic systems also exacerbates the adverse effects of excess heat.

Carbon materials, represented by graphite, have been attracting attention as materials with excellent heat control. Graphite has a heat conductivity equivalent to that of aluminum and copper, which are common high heat conductive materials, and has better heat transport properties than copper. For this reason, graphite has been attracting attention as a material for heat dissipation fins used in heat spreaders for LSI chips and heat sinks for semiconductor power modules. In conventional heat sinks using carbon materials, for example, as shown in Patent Document 3 (JP2009505850), a heat sink has been proposed in which brittle carbon particles are compressed and solidified, and then coated with a metal film, thereby preventing the peeling of graphite while taking advantage of the high heat conductivity of carbon.

### SUMMARY OF INVENTION

### Technical Problem

However, the space radiator of Patent Document 1 has a rigid structure, has a large mass, lacks flexibility, and may be unusable or restricted in handling depending on the application. Since the coolant flow path for heat dissipation or absorption is disposed on a plane, the piping portion acting as the coolant flow path and the portion with the heat radiation or heat absorption surface are separate parts, resulting in a complex structure and high cost.

In Patent Document 2, mechanical drive such as a paddle is used, which not only gives rise to concerns about malfunction, but also renders the device heavy, making it difficult to apply it to small satellites.

The heat sink of Patent Document 3 is fabricated by compressing graphite particles, and hence does not have a dense graphite structure in the planar direction, resulting in low strength and low heat transport performance.

The object of the present disclosure is to solve the above problems and to provide a heat control structure adapted to environments with large temperature differences in outer space and on Earth by improving heat dissipation and heat transport properties through a lightweight and simple mechanism, and an artificial satellite equipped with the same.

### Means For Solving Problem

A heat control structure according to one aspect of the present disclosure includes: a plurality of sheet-like or plate-like graphite members; a first holding member that holds the plurality of graphite members at first ends in a longitudinal direction of the plurality of graphite members with basal planes of the graphite members arrayed in parallel and with edge planes orthogonal to the basal planes being exposed; and a second holding member that holds the plurality of graphite members at second ends opposite to the first ends of the plurality of graphite members with the basal planes arrayed in parallel and with the edge planes being exposed. The edge planes exposed at the first ends of the plurality of graphite members come into contact with a heat control target to function as heat transfer surfaces through which heat energy is input, while the edge planes exposed at the second ends come into contact with a heat dissipation target to function as heat transfer surfaces through which heat energy is dissipated.

A satellite according to one aspect of the present disclosure includes the heat control structure of the above aspect, the edge planes exposed at the first ends of the plurality of graphite members being positioned in contact with the heat control target within the satellite, the edge planes exposed at the second ends of the plurality of graphite members being positioned facing an exterior space of the satellite.

### EFFECT OF INVENTION

According to the present disclosure, there can be provided a heat control structure adapted to environments with large temperature differences in outer space and on Earth by improving heat dissipation and heat transport properties through a lightweight and simple mechanism, and an artificial satellite equipped with the same.

### BRIEF DESCRIPTION OF DRAWINGS

FIG. 1 is a schematic view of a heat control structure in an embodiment of the present disclosure.

FIG. 2 is an external view of the heat control structure of the embodiment.

FIG. 3 is an external view of the heat control structure of the embodiment.

FIG. 4A is a structural view of the vicinity of a base plate in the heat control structure of the embodiment.

FIG. 4B is an exploded view of the base plate shown in FIG. 4A.

FIG. 5 is a schematic view of a heat control structure according to a variant of the embodiment.

FIG. 6 is a schematic view of a TEG for a heat conductivity evaluation test.

FIG. 7 is a table showing the results of a heat conductivity evaluation test and a shape change evaluation after a vibration test for the heat control structures of Examples and Comparative Examples.

### DESCRIPTION OF EMBODIMENTS

A heat control structure according to a first aspect of the present disclosure includes: a plurality of sheet-like or plate-like graphite members; a first holding member that holds the plurality of graphite members at first ends in a longitudinal direction of the plurality of graphite members with basal planes of the graphite members arrayed in parallel and with edge planes orthogonal to the basal planes being exposed; and a second holding member that holds the plurality of graphite members at second ends opposite to the first ends of the plurality of graphite members with the basal planes arrayed in parallel and with the edge planes being exposed. The edge planes exposed at the first ends of the plurality of graphite members come into contact with a heat control target to function as heat transfer surfaces through which heat energy is input, and the edge planes exposed at the second ends come into contact with a heat dissipation target to function as heat transfer surfaces through which heat energy is dissipated.

The heat control structure according to a second aspect of the present disclosure is such that in the first aspect, the first holding member holds the plurality of graphite members with the edge planes of the plurality of graphite members lying in the same plane.

The heat control structure according to a third aspect of the present disclosure is such that in the first or second aspect, the second holding member holds the plurality of graphite members with the edge planes of the plurality of graphite members lying in the same plane.

The heat control structure according to a fourth aspect of the present disclosure is such that in any one of the first to third aspects, the first holding member and the second holding member have a structure that holds the plurality of graphite members by clamping them in a direction orthogonal to the basal planes.

The heat control structure according to a fifth aspect of the present disclosure is such that in any one of the first to fourth aspects, the first holding member and the second holding member hold the plurality of graphite members with the basal planes of adjacent graphite members spaced apart from each other.

The heat control structure according to a sixth aspect of the present disclosure is such that in any one of the first to fifth aspects, it comprises a heat radiating member disposed in contact with the exposed edge planes at the second ends of the plurality of graphite members.

The heat control structure according to a seventh aspect of the present disclosure is such that in any one of the first to sixth aspects, the graphite member includes a graphite sheet or a graphite plate and the graphite sheet and that the graphite sheet and the graphite plate are made from a polymer film.

The heat control structure according to an eighth aspect of the present disclosure is such that in the seventh aspect, the polymer film is made of at least one of the group consisting of polyoxadiazole, polybenzothiazole, polybenzobisthiazole, polybenzoxazole, polybenzobisoxazole, polypyromellitimide, aromatic polyamide, polyphenylene benzimidazole, polyphenylene benzobisimidazole, polythiazole, and polyparaphenylene vinylene. By forming the polymer film using such a material, the graphite member is allowed to have a graphite structure.

A satellite according to a ninth aspect of the present disclosure is a satellite comprising the heat control structure of any one of the first to eighth aspects, the edge planes exposed at the first ends of the plurality of graphite members being positioned in contact with the heat control target within the satellite, the edge planes exposed at the second ends of the plurality of graphite members being positioned facing an exterior space of the satellite.

### Embodiment

An embodiment of the present disclosure will hereinafter be described with reference to the drawings.

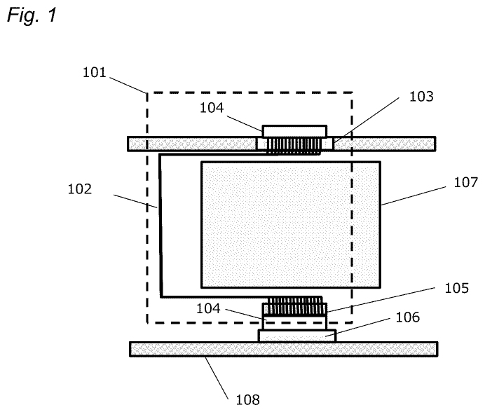

A schematic structure of a heat control structure 101 in an embodiment of the present disclosure is shown in FIG. 1. The case where the heat control structure 101 is installed in a housing 108 of a satellite will be described as an example. The heat control structure 101 of the embodiment is a structure that transports heat energy generated in a heat control target to a different location to dissipate the heat energy into a heat dissipation target. The heat control target may be any target that generates heat, such as an electronic device or electronic component disposed in a satellite. The heat dissipation target may be any target into which the transported heat energy is dissipated by heat transfer or radiation, such as outer space, which is the external space of the housing 108 of the satellite.

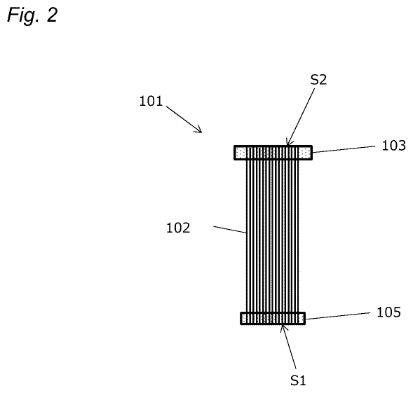

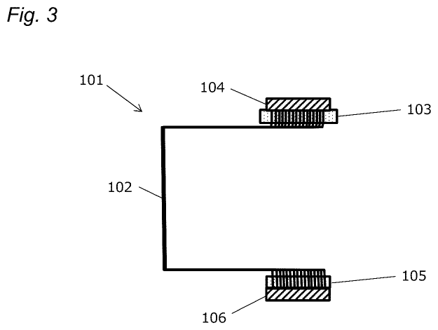

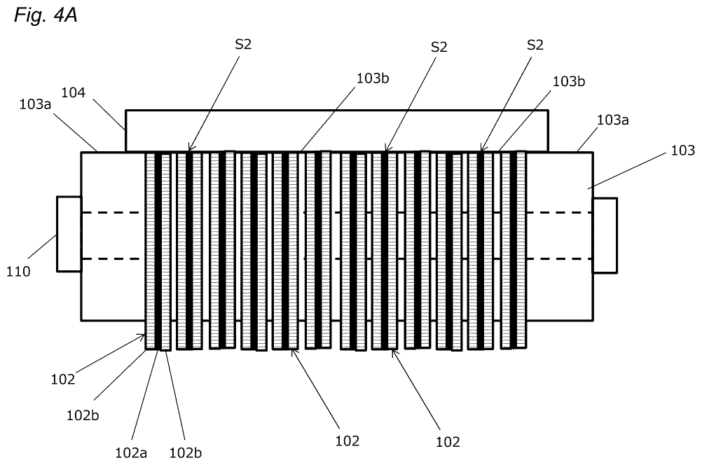

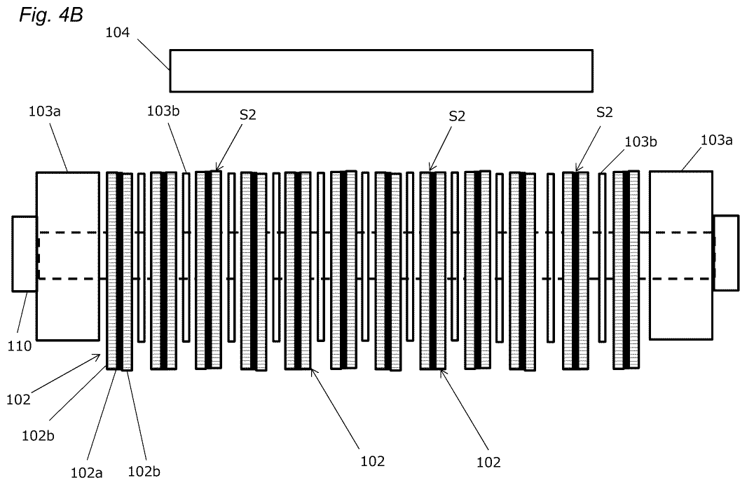

External views of the heat control structure 101 are shown in FIGS. 2 and 3, and a structural view of the vicinity of a base plate in heat control structure 101 is shown in FIG. 4. The heat control structure 101 includes a plurality of graphite members 102, and base plates 103 and 105 that hold the longitudinal ends of the graphite members 102.

The graphite member 102 is a member in which the surface of a graphite sheet 102a is protected by a protective layer 102b. One or more polymer films are fired while controlling the applied pressure to produce a highly oriented graphitized graphite sheet 102a, which is then coated with a coating agent to produce a graphite member 102 having a protective layer 102b formed on the surface. Various coating methods may be applied, such as polyimide tape, liquid polyimide, metal plating, and metal powder welding. The coating range may be appropriately determined depending on the parts in contact with the base plates 103 and 105, the frequency of insulation and bending, and the like. For example, the coating range may be the entire graphite member 102. The polymer film may be at least one of the group consisting of polyoxadiazole, polybenzothiazole, polybenzobisthiazole, polybenzoxazole, polybenzobisoxazole, polypyromellitimide, aromatic polyamide, polyphenylenebenzimidazole, polyphenylenebenzobisimidazole, polythiazole, and polyparaphenylenevinylene. When the graphite sheet is made by compressing graphite powder, it is brittle in strength and has low heat transport performance because no dense graphite structure is formed in the planar direction, i.e., because the six-membered rings consisting of carbon atoms are shredded and broken into pieces and pressed together. As a result, higher heat dissipation, which is the original purpose, cannot be achieved. In contrast, the graphite sheet 102a formed using the polymer film described above is highly crystalline, with the six-membered rings consisting of carbon atoms uniformly arranged in the planar direction, and thus has high heat transport performance. In contrast, the graphite sheet 102a formed using the above polymer film has a high crystallinity in which the six-membered rings consisting of carbon atoms are uniformly arranged in the planar direction, so that the heat transport performance is also high.

The first base plate 105 holds the plurality of graphite members 102 at a first end in the longitudinal direction of the graphite members 102. The second base plate 103 holds the plurality of graphite members 102 at a second end opposite to the first end of the graphite members 102. In the graphite member 102, heat energy is input from a heat control target to the first end side of graphite member 102 and is released from the second end side.

The graphite sheet 102a has a layered structure of benzene-condensed planes, where the benzene-condensed planes are basal planes and the planes orthogonal to the basal planes are edge (non-basal) planes. The graphite sheet 102a has a feature that the heat conductivity in the direction along the basal planes is significantly higher than the heat conductivity in the direction orthogonal to the basal planes. The graphite member 102 is cut depending on the heat transport distance to form the first end and the second end, so that the edge planes of graphite sheet 102a are exposed from the protective layer 102b at the first end and the second end.

The structure of the second base plate 103 is shown in FIGS. 4A and 4B. FIG. 4A is a view showing the assembled state of the second base plate 103, while FIG. 4B is a view showing the disassembled state. As shown in FIGS. 4A and 4B, the second base plate 103 includes two end plates 103a that clamp the plurality of graphite members 102 from both ends, and a plurality of spacer plates 103b arranged between the adjacent graphite members 102. At the second ends of the plurality of graphite members 102, the graphite members 102 are held by being clamped by the two end plates 103a arranged on both end sides with the spacer plates 103b arranged between the adjacent graphite members 102. For example, the graphite members 102 can be clamped and held by tightening a caulking jig 110 disposed through the end plates 103a and the spacer plates 103b in a direction orthogonal to the end plates 103a in the second base plate 103. The caulking jig 110 may be a metal bolt or a hollow metal pipe.

The plurality of graphite members 102 are in a state where the opposing basal planes are sandwiched between the end plates 103a or the spacer plates 103b. In this state, the edge planes S2 of the graphite members 102 are exposed from the second base plate 103, that is, between the end plates 103a or the spacer plates 103b. As shown in FIG. 4, the edge planes S2 of the exposed graphite sheets 102a are located, for example, in the same plane. A heat transfer member 104 is disposed so as to be in contact with the exposed edge planes S2. Since the edge planes S2 are located in the same plane, it is easy to dispose the edge planes S2 in contact with the surface of the heat transfer members 104. As such a heat transfer member 104, a member having high heat conductivity can be used, and for example, a metal member such as aluminum may be used.

By disposing the spacer plate 103b between the graphite members 102 held by the second base plate 103, the graphite members 102 are disposed apart from each other in the thickness direction. This allows the exposed edge plane S2 to be spaced apart from the adjacent edge plane S2, thereby enhancing heat conductivity. The graphite members 102 are easier to handle if they are highly flexible, and hence it is desirable to form the graphite sheets 102a to have a thin thickness. The size of the heat transfer member 104 is determined depending on the target of heat energy input or dissipation. Even if the heat transfer surface of the heat transfer member 104 is sufficiently larger than the thickness of the graphite member 102, the graphite sheets 102a are spaced apart from each other so that the respective edge planes S2 can distributedly be brought into contact with the heat transfer surface. For example, the ratio of the thickness of the graphite sheets 102a to the arrangement pitch of the graphite sheets 102a may be 1:5 or more.

Although the holding structure for the graphite member 102 has been described using the second base plate 103 as an example, a similar holding structure is adopted for the first base plate 105 as well. In the first base plate 105, an exposed edge plane S1 is in contact with the heat transfer member 104 (see FIG. 3).

In the graphite member 102, the edge plane S1 exposed at the first end functions as a heat transfer surface to which heat energy is input from the heat transfer member 104. The edge plane S2 exposed at the second end functions as a heat transfer surface that dissipates heat energy by coming into contact with a heat dissipation target (for example, the heat transfer member 104). Note that the plurality of graphite members 102 are held by the base plates 103 and 105 so as to be spaced apart from each other at the first end and the second end, but the graphite members 102 may overlap each other between the first end and the second end. Thus, the graphite members 102 can compactly be organized and can also be made into a two-dimensional cable, enhancing handleability.

Referring to FIG. 1, the state will be described where the heat control structure 101 having such a configuration is arranged in a satellite. As shown in FIG. 1, the heat control target 106 is disposed inside the housing 108 of the satellite. The heat transfer member 104 is arranged so as to be in contact with the heat control target 106, and the edge plane S1 on the first end side of the graphite member 102 is in contact with the heat transfer member 104. The second base plate 103 holding the second end of the graphite member 102 is disposed in the housing 108 of the satellite, and the edge plane S2 on the second end side of the graphite member 102 is exposed to the outside of the housing 108. The heat transfer member 104 is arranged so as to be in contact with the edge plane S2, and the heat transfer member 104 is arranged outside the housing 108, i.e., in outer space. The graphite member 102 is arranged by utilizing its flexibility so as not to interfere with a non-heat-control target 107 arranged inside the housing 108. The graphite member 102 may be a graphite plate. To transport heat in the narrow space of a small satellite, it is preferable to use a highly flexible sheet-like graphite member. On the other hand, if a space for heat transport can be secured, a graphite plate that is more linear and capable of high-heat transport may be used. The graphite sheet refers to a sheet made of raw material having a thickness of, for example, approx. 30 μm, softened by expanding the gas contained therein. On the other hand, the graphite plate is a sheet made of raw material having a thickness of, for example, approx. 100 μm, pressurized while removing the gas contained therein to give it rigidity.

Heat energy generated in the heat control target 106 is input from the edge plane S1 on the first end side of the graphite member 102 via the heat transfer member 104. The heat energy input from the edge plane S1 is thermally transported along the basal plane in the plurality of layers of the graphite sheet 102a. In the direction along the basal plane, the hexagonal rings of carbon atoms are uniformly arranged, allowing thermal vibrations to be rapidly transmitted. On the other hand, in the thickness direction of the graphite sheet 102a, the layers are connected only by intermolecular forces, so that thermal vibrations are not easily transmitted, resulting in heat conductivity of about 1/100 of that in the direction along the basal plane. Hence, compared to the case where heat energy is input from the basal plane, the case where heat energy is input from the edge plane S1 allows heat energy to be transmitted to each layer more uniformly, achieving efficient heat transport.

Heat is transported from the first end to the second end along the graphite sheet 102a, and the heat energy is transferred from the edge plane S2 exposed at the second end to the heat transfer member 104. Since the heat transfer member 104 is disposed in outer space, the transferred heat energy is dissipated by being radiated into outer space. In particular, since there is no convection in outer space, it is possible to further enhance the heat dissipation by radiating heat. Since the edge plane S2 of the graphite sheet 102a is in contact with the heat transfer member 104 (heat radiation member), heat can be transferred more efficiently than when the basal plane is in contact.

Although the case has been described as an example where the edge planes S1 and S2 of the graphite sheet 102a are in contact with the heat transfer member 104, the present invention is not limited to such a case. For example, the edge plane S1 may be in direct contact with the heat control target 106 without using the heat transfer member 104, or the edge plane S2 may be disposed outside the housing 108 so as to face outer space.

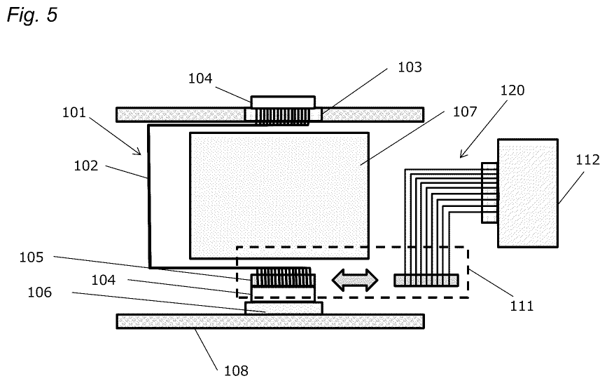

As a variant of the present embodiment, as shown in FIG. 5, instead of discharging heat energy to the outside of the housing 108, heat may be stored in a heat storage unit 112. For example, there may be disposed the heat control structure 101 discharging heat energy from the heat control target 106 to the outside of the housing 108 and a heat control structure 120 storing heat energy from the heat control target 106 in the heat storage unit 112, and the one coming into contact with the heat control target 106 may selectively be switched. A switching mechanism 111 may be used as a switching means. Depending on the amount of heat generated by the heat control target 106 and the status of the satellite, the heat energy stored in the heat storage unit 112 can be used to maintain thermal equilibrium within the satellite. The heat storage unit 112 contains a heat storage material that stores/discharges heat by undergoing a phase change. The heat control structure 120 has a substantially similar structure to the heat control structure 101, although the thermally connected target is different.

### EXAMPLES

Examples and Comparative Examples of the heat control structure of the present disclosure will then be described.

### Example 1

As a heat transport element 102 according to Example 1 of the present disclosure, a PGS graphite sheet (manufactured by Panasonic Ltd., t=100 μm) was used, and 25 graphite sheets with a length of 80 mm and a width of 25 mm were used. The second base plate 103 and the first base plate 105 were rectangular members of 30 mm×30 mm, with graphite sheets arranged at a pitch of 0.8 mm and made of Al5052. The coating agent was liquid polyimide PI-150 (manufactured by Koyo Trading) applied to the entire surface of the sheet with a thickness of 100 μm and then cured and dried at 180° C. to form the protective layer 102b. A 3-mm diameter copper pipe was used as the caulking jig 110. The heat control structure 101 shown in FIG. 2 was fabricated with the pressure during caulking controlled to 35 N.

The performance and reliability of the heat control structure thus fabricated were evaluated through heat conductivity tests and vibration tests, on the assumption that it would be installed on an actual satellite.

### Example 2

A heat control structure was fabricated under the same conditions as in Example 1 except that a graphite plate (t=100 μm) which is stiffer than the graphite sheet used in Example 1 was used instead of the graphite sheet.

### Example 3

A heat control structure was fabricated in which the heat transfer member 104 was disposed on the second end side exposed to outer space in the heat control structure of Example 1, with the other conditions being the same as those of Example 1. This heat control structure corresponds to the heat control structure shown in FIG. 3.

### Comparative Example 1

As Comparative Example 1, a heat control structure was fabricated under the same conditions as in Example 1, except that a 100-μm thick copper foil was used as the heat transport member instead of the graphite member.

### Comparative Example 2

As Comparative Example 2, a heat control structure was fabricated using a conventional rigid heat pipe as the heat transport member.

### Evaluation Method

### Heat Conductivity Evaluation Test

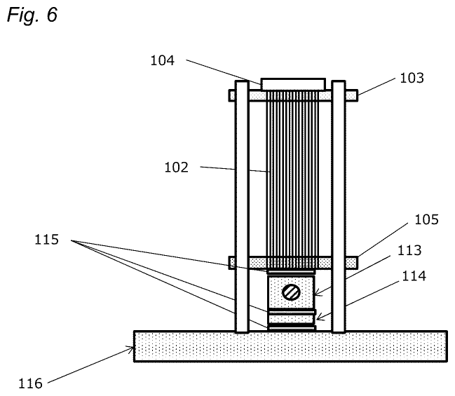

A heat conductivity evaluation test was performed on the heat control structures fabricated in Examples 1 to 3 and Comparative Examples 1 and 2. The heat conductivity evaluation TEG was performed using a test device shown in FIG. 6. In the evaluation in a natural cooling environment, a temperature measuring part 113 (10 mm×10 mm, t: 5 mm, made of copper) and a heater 114 (10 mm×10 mm, t: 1 mm, made of ceramic) were attached directly under the center of the graphite heat sink described in the heat control structures of Examples 1 to 3 and Comparative Example 1 and 2 by applying grease 115 to a thickness of 0.3 mm. These components were arranged on a base 116, and the temperature of the boundary between the heater and the heat control structure was measured and evaluated when the heater was operated with a heater input of 11 V. As an evaluation criterion, if the temperature of the measurement part was less than 70° C., it was determined that heat control was performed sufficiently. Note that the graphite heat sink is a heat sink that uses a graphite material as a fin or a fin and a base.

### Shape Evaluation After Vibration Test

For Examples 1 to 3 and Comparative Examples 1 and 2, a vibration test was carried out in accordance with JIS60068 Feb. 6, and then a shape change evaluation was carried out on the heat control structure. The evaluation criteria were as follows.

○: No visible change in shape
×: Graphite member or copper foil collapsed, peeled off, or broke

### Considerations

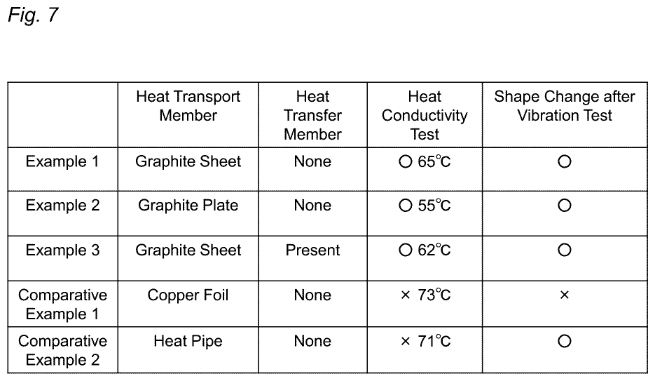

FIG. 7 is a table showing the results of a heat conductivity evaluation test and a shape change evaluation after a vibration test for the heat control structures of Examples 1 to 3 and Comparative Examples 1 and 2.

As shown in Example 1, by exposing the edge plane of the graphite sheet to the heat control target and its opposite surface, the results were obtained that the heat conductivity was improved and that the flexibility of the graphite sheet brought about strong vibration resistance. In Example 2, a rigid graphite plate is used, but the protective layer formed by the coating agent ensures slippage with the base plate, and vibration resistance is also maintained. This slippage refers to the cushioning effect of the viscoelastic coating agent. Furthermore, in Example 3, the use of a heat transfer member makes it possible to expect heat radiation into outer space.

On the other hand, as shown in Comparative Example 1, when copper foil is used, it cannot achieve the same heat dissipation as graphite in a small area, and the vibration resistance is also weak, so that the shape cannot be secured. In Comparative Example 2, a heat pipe is used, so that it is heavy, lacks flexibility, and has a complicated structure, as described above.

The heat control structure 101 of the present embodiment includes the plurality of graphite members 102, the first base plate 105 that holds the plurality of graphite members 102 at the first end in the longitudinal direction of the graphite members 102, and the second base plate 103 that holds the plurality of graphite members 102 at the second end opposite to the first end. The graphite members 102 may be of a sheet or plate shape. The first base plate 105 holds the plurality of graphite members 102 at the first end such that the basal planes are arranged in parallel and the edge planes S1 orthogonal to the basal planes are exposed. The second base plate 103 holds the plurality of graphite members 102 at the second end such that the basal planes are arranged in parallel and the edge planes S2 are exposed. The edge planes S1 exposed at the first ends of the plurality of graphite members 102 come into contact with the heat control target 106 to function as a heat transfer surface to which heat energy is input. The edge planes S2 exposed at the second end portion come into contact with a heat dissipation target to function as a heat transfer surface that dissipates heat energy.

Such a structure makes it possible to provide a heat control structure that is overwhelmingly lighter than metal due to the use of graphite and that can achieve high heat dissipation and heat transport properties with a simple mechanism that does not use paddles, etc. In particular, this heat control structure is suitable for environments with large temperature differences, such as outer space and on Earth, also rendering it possible to provide an artificial satellite equipped with such a heat control structure.

Any of the above various embodiments can be combined as appropriate to achieve their respective effects.

### INDUSTRIAL APPLICABILITY

The heat control structure of the present disclosure is applicable not only to spacecraft and artificial satellites, but also to heat absorption and dissipation applications for heat control targets in industrial equipment and automotive fields.

### REFERENCE SIGNS LIST

101, 120 heat control structure
102 graphite member
102a graphite sheet
102b protective layer
103 second base plate (cooling side)
103a end plate
103b spacer plate
104 heat transfer member
105 first base plate (heat control target side)
106 heat control target
107 non-heat-control target
108 satellite housing
109 protective layer
110 caulking jig
111 switching mechanism
112 heat storage unit
S1, S2 edge plane

1. A heat control structure comprising:
a plurality of sheet-like or plate-like graphite members;
a first holding member that holds the plurality of graphite members at first ends in a longitudinal direction of the plurality of graphite members with basal planes of the graphite members arrayed in parallel and with edge planes orthogonal to the basal planes being exposed; and
a second holding member that holds the plurality of graphite members at second ends opposite to the first ends of the plurality of graphite members with the basal planes arrayed in parallel and with the edge planes being exposed, wherein
the edge planes exposed at the first ends of the plurality of graphite members come into contact with a heat control target to function as heat transfer surfaces through which heat energy is input, and
the edge planes exposed at the second ends come into contact with a heat dissipation target to function as heat transfer surfaces through which heat energy is dissipated.

2. The heat control structure according to claim 1, wherein the first holding member holds the plurality of graphite members with the edge planes of the plurality of graphite members lying in the same plane.

3. The heat control structure according to claim 1, wherein the second holding member holds the plurality of graphite members with the edge planes of the plurality of graphite members lying in the same plane.

4. The heat control structure according to claim 1, wherein the first holding member and the second holding member have a structure that holds the plurality of graphite members by clamping them in a direction orthogonal to the basal planes.

5. The heat control structure according to claim 1, wherein the first holding member and the second holding member hold the plurality of graphite members with the basal planes of adjacent graphite members spaced apart from each other.

6. The heat control structure according to claim 1, comprising a heat radiating member disposed in contact with the exposed edge planes at the second ends of the plurality of graphite members.

7. A satellite comprising the heat control structure according to claim 1, wherein
the edge planes exposed at the first ends of the plurality of graphite members are positioned in contact with the heat control target within the satellite, and
the edge planes exposed at the second ends of the plurality of graphite members are positioned facing an exterior space of the satellite.
